(19) United States
(12) Patent Application Publication
(10) Pub. No.: US 2025/0087644 A1
(43) Pub. Date: Mar. 13, 2025

(54) MANUFACTURING METHOD OF DISPLAY PANEL AND SPLICED DISPLAY PANEL

(71) Applicants: HUIZHOU CHINA STAR OPTOELECTRONICS DISPLAY CO., LTD., Huizhou, Guangdong (CN); TCL CHINA STAR OPTOELECTRONICS TECHNOLOGY CO., LTD., Shenzhen, Guangdong (CN)

(72) Inventors: Zhuhui LI, Huizhou, Guangdong (CN); Yanfen LI, Huizhou, Guangdong (CN)

(73) Assignees: HUIZHOU CHINA STAR OPTOELECTRONICS DISPLAY CO., LTD., Huizhou, Guangdong (CN); TCL CHINA STAR OPTOELECTRONICS TECHNOLOGY CO., LTD., Shenzhen, Guangdong (CN)

(21) Appl. No.: 18/558,196

(22) PCT Filed: May 25, 2023
(86) PCT No.: PCT/CN2023/096319

§ 371 Date: Oct. 31, 2023

(30) Foreign Application Priority Data
Apr. 25, 2023 (CN) 202310463045.1

(51) Int. Cl. H01L 25/075; H01L 33/62

(52) U.S. Cl. CPC H01L 25/0753; H10H 20/857; H10H 20/0364

(57) ABSTRACT

A manufacturing method of a display panel and a spliced display panel are provided, wherein the manufacturing method of a display panel includes the following steps: at least forming a silver nanowire layer on a lateral end surface of a substrate to be processed. An ultraviolet laser is used to sinter the silver nanowire layer. The silver nanowire layer is patterned to form multiple connection wires connected between the first connection terminal and the corresponding second connection terminal. The configuration prevents insufficiently tight or poor contact between silver nanowires.

### TECHNICAL FIELD

The present disclosure relates to a field of display technologies and in particular, to a manufacturing method of a display panel and a spliced display panel.

### DESCRIPTION OF RELATED ART

Miniature light-emitting diodes (mini LED or micro LED) have been used in display panels, such as mini LEDs serving as backlight sources for liquid crystal display panels, or micro-LED display panels used for outdoor displays. However, limited by the miniature LED transfer technology, it is difficult to achieve single-piece large-sized displays with miniature LEDs. It requires the splicing of multiple small-sized miniature LED display modules to form a large-sized display panel. When splicing miniature LED display modules into a large-sized display panel, gaps between the spliced modules significantly degrade the overall integrity of the displayed image. In order to achieve seamless splicing, a lateral-side silver paste transfer technology has been developed. This technology involves transferring silver paste onto the sides of micro LED display modules to create wire connections that link the front-facing driving circuits.

However, the wire impedance formed by the lateral-side silver paste transfer technology is high, and the silver paste is prone to detachment.

### SUMMARY OF INVENTION

The present application provides an array substrate side alignment manufacturing method and a spliced display panel to solve the problems of high wire impedance and easy detachment of silver paste formed by the lateral-side silver paste transfer technology.

The present application provides a manufacturing method of a display panel, including following steps:

providing a substrate to be processed, wherein the substrate to be processed includes a first surface, a second surface, and a lateral end surface disposed between the first surface and the second surface, the first surface is provided with a first connection terminal, and the second surface is provided with a second connection terminal corresponding to the first connection terminal;

forming a first protective layer at least on the first surface, the first protective layer non-overlapping with the first connection terminal;

forming a silver nanowire layer at least on the lateral end surface of the substrate to be processed, wherein the silver nanowire layer is connected to the first connection terminal and the second connection terminal;

sintering the silver nanowire layer with an ultraviolet laser; and

patterning the silver nanowire layer to form a plurality of connection wires, wherein the connection wires are connected between the first connection terminal and the second connection terminal corresponding to the first connection terminal.

Optionally, in some embodiments of the present application, before the step of sintering the silver nanowire layer with the ultraviolet laser, the silver nanowire layer includes a plurality of silver nanowires; and

after the step of sintering the silver nanowire layer with the ultraviolet laser, the silver nanowires that are in contact with each other are fused together.

Optionally, in some embodiments of the present application, the step of patterning the silver nanowire layer to form the plurality of connection wires is performed by using laser irradiation.

Optionally, in some embodiments of the present application, the step of forming the first protective layer at least on the first surface further comprises:

forming a second protective layer on the second surface, the second protective layer non-overlapping with the second connection terminal.

Optionally, in some embodiments of the present application, the first protective layer is produced by coating or attaching.

Optionally, in some embodiments of the present application, a material of the first protective layer includes polyimide.

Optionally, in some embodiments of the present application, the step of forming the silver nanowire layer at least on the lateral end surface of the substrate to be processed further comprises:

forming the silver nanowire layer on the first connection terminal of the first surface and the second connection terminal of the second surface.

Accordingly, the present application further provides a spliced display panel, including a first sub-display panel and a second sub-display panel spliced with each other, a manufacturing method of the first sub-display panel including following steps:

providing a substrate to be processed, wherein the substrate to be processed comprises a first surface, a second surface, and a lateral end surface disposed between the first surface and the second surface, the first surface is provided with a first connection terminal, and the second surface is provided with a second connection terminal corresponding to the first connection terminal;

forming a first protective layer at least on the first surface, the first protective layer non-overlapping with the first connection terminal;

forming a silver nanowire layer at least on the lateral end surface of the substrate to be processed, wherein the silver nanowire layer is connected to the first connection terminal and the second connection terminal;

sintering the silver nanowire layer with an ultraviolet laser; and

patterning the silver nanowire layer to form a plurality of connection wires, wherein the connection wires are connected between the first connection terminal and the second connection terminal corresponding to the first connection terminal,

wherein the second connection terminal of the first sub-display panel is electrically connected to a driving chip.

Optionally, in some embodiments of the present application, the spliced display panel further includes a plurality of micro light-emitting diodes (LEDs) or mini LEDs arranged in an array on the first sub-display panel and the second sub-display panel.

Optionally, in some embodiments of the present application, the micro LEDs are used as a backlight source of the spliced display panel or as sub-pixels for displaying images.

Optionally, in some embodiments of the present application, before the step of sintering the silver nanowire layer with the ultraviolet laser, the silver nanowire layer comprises a plurality of silver nanowires; and

after the step of sintering the silver nanowire layer with the ultraviolet laser, the silver nanowires that are in contact with each other are fused together.

Optionally, in some embodiments of the present application, the step of patterning the silver nanowire layer to form the plurality of connection wires is performed by using laser irradiation.

Optionally, in some embodiments of the present application, the step of forming the first protective layer at least on the first surface further comprises:

forming a second protective layer on the second surface, the second protective layer non-overlapping with the second connection terminal.

Optionally, in some embodiments of the present application, the first protective layer is produced by coating or attaching.

Optionally, in some embodiments of the present application, a material of the first protective layer includes a polyimide.

Optionally, in some embodiments of the present application, the step of forming the silver nanowire layer at least on the lateral end surface of the substrate to be processed further comprises:

forming the silver nanowire layer on the first connection terminal of the first surface and the second connection terminal of the second surface.

### ADVANTAGES

In an embodiment of the present application, a manufacturing method of a display panel and a spliced display panel is provided. The manufacturing method of the display panel includes the following steps: providing a substrate to be processed, the substrate to be processed including a first surface, a second surface, and a lateral end surface disposed between the first surface and the second surface, the first surface provided with a first connection terminal, and the second surface provided with a second connection terminal corresponding to the first connection terminal; forming a first protective layer at least on the first surface, and the first protective layer disposed away from the first connection terminal; forming a silver nanowire layer at least on the lateral end surface of the substrate to be processed, and the silver nanowire layer connecting to the first connection terminal and the second connection terminal; sintering the silver nanowire layer with an ultraviolet laser; patterning the silver nanowire layer to form a plurality of connection wires, wherein each of the connection wires is connected between the first connection terminal and the second connection terminal corresponding to the first connection terminal. In the present application, the silver nanowire layer is formed on the lateral end surface of the substrate to be processed, and the silver nanowire layer is sintered by using an ultraviolet laser, so that a contact or adhesion performance of the connection wire and the substrate to be processed is enhanced, and the connection wire is prevented from falling off. At the same time, the silver nanowire layer is sintered by the ultraviolet laser, silver nanowires in contact with each other are fused together, thereby avoiding the contact between the silver nanowires is not close enough or the contact is poor to reduce the impedance of the connection wire.

### BRIEF DESCRIPTION OF DRAWINGS

In order to more clearly illustrate the technical solutions of the present application, the drawings that need to be used in the description of the embodiments are briefly introduced below.

Obviously, the drawings in the following description are only some of the embodiments of the present application. For those skilled in the art, other drawings can be obtained based on these drawings without creative efforts.

FIG. 1 is a process flow diagram illustrating a manufacturing method of a display panel according to one embodiment of the present application.

FIG. 2 is a schematic view of a first surface in a first intermediate step of the manufacturing method of the display panel according to one embodiment of the present application.

FIG. 3 is a schematic view of a second surface in the first intermediate step of the manufacturing method of the display panel according to one embodiment of the present application.

FIG. 4 is a first cross-sectional view along a dashed line C-D direction in FIG. 2.

FIG. 5 is a second cross-section view along the dashed line C-D direction in FIG. 2, showing a situation where a first connection terminal and a corresponding second connection terminal are adjacent to or connected to a lateral end surface.

FIG. 6 is a schematic view of the first surface in a second intermediate step of the manufacturing method of the display panel according to one embodiment of the present application.

FIG. 7 is a schematic view of the first surface in a third intermediate step of the manufacturing method of the display panel according to one embodiment of the present application.

FIG. 8 is a schematic view showing a state before sintering of a silver nanowire layer according to one embodiment of the present application.

FIG. 9 is a schematic view of the first surface in a fourth intermediate step of the manufacturing method of the display panel according to one embodiment of the present application.

FIG. 10 is a schematic view showing a state after sintering of the silver nanowire layer according to one embodiment of the present application.

FIG. 11 is a schematic view of the first surface in a fifth intermediate step of the manufacturing method of the display panel according to one embodiment of the present application.

FIG. 12 is a schematic view of the first surface in a sixth intermediate process of the manufacturing method of the display panel according to one embodiment of the present application.

FIG. 13 is a schematic cross-sectional view of the display panel according to one embodiment of the present application.

FIG. 14 is a schematic view of a spliced display panel according to one embodiment of the present application.

### DETAILED DESCRIPTION OF EMBODIMENTS OF THE INVENTION

The technical solutions of the present application are clearly and completely described below in conjunction with the accompanying drawings with reference to specific embodiments. Apparently, the described embodiments are only some of the embodiments of the present application, not all of them. Based on the embodiments in the present application, all other embodiments obtained by those skilled in the art without making creative efforts are deemed to fall within the protection scope of the present application. Furthermore, it should be understood that the specific embodiments described here are merely intended to illustrate and explain the present application and are not intended to limit the scope of the present application. In the present application, unless specified to the contrary, the directional terms “up” and “down” usually refer to the actual use or working condition of the device, especially the directions shown in the accompanying drawings, while the terms “inside” and “outside” are referred to with respect to the outlines of the device.

One embodiment of the present application provides a manufacturing method for a display panel, including the following steps: providing a substrate to be processed, wherein the substrate to be processed includes a first surface, a second surface, and a lateral end surface disposed between the first surface and the second surface, the first surface is provided with a first connection terminal, and the second surface is provided with a second connection terminal corresponding to the first connection terminal; forming a first protective layer at least on the first surface, the first protective layer non-overlapping with the first connection terminal; forming a silver nanowire layer at least on the lateral end surface of the substrate to be processed, wherein the silver nanowire layer is connected to the first connection terminal and the second connection terminal; sintering the silver nanowire layer with ultraviolet laser; and patterning the silver nanowire layer to form a plurality of connection wires, wherein the connection wires are connected between the first connection terminal and the second connection terminal corresponding to the first connection terminal.

The present application further provides a spliced display panel formed by the above-mentioned manufacturing method of the display panel. The spliced display panel is described in detail below. It should be noted that the description sequence of the following embodiments is not intended to limit the preferred sequence of the embodiments.

### First Embodiment

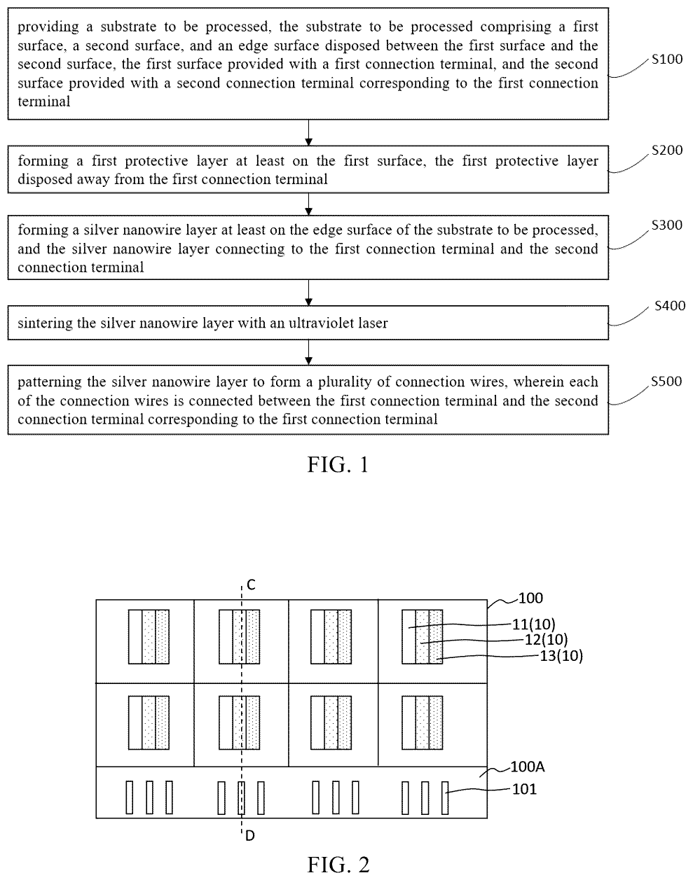

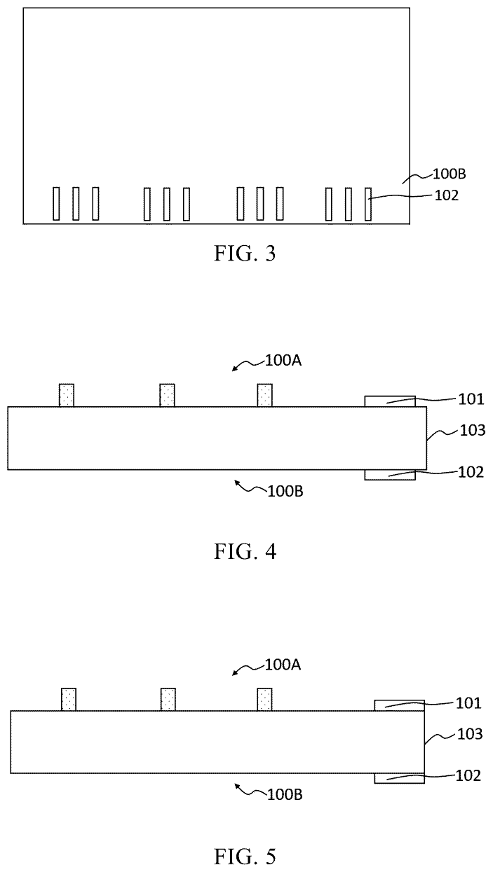

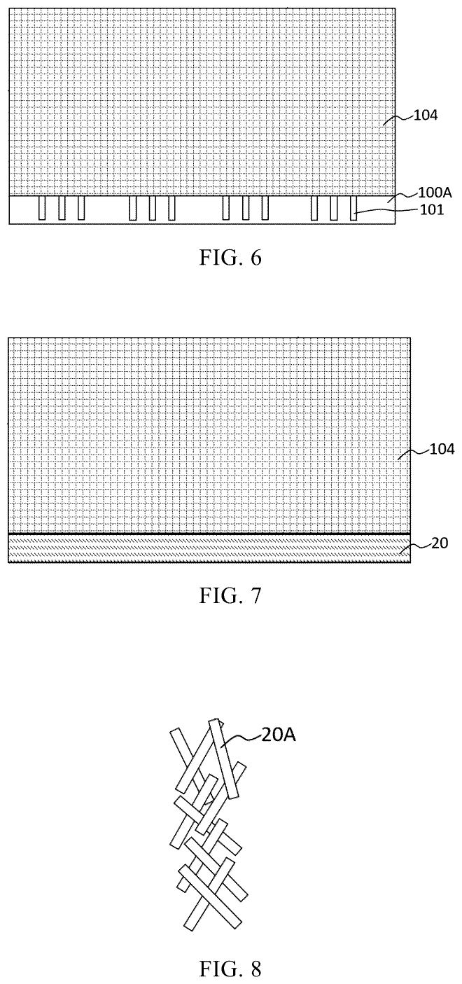

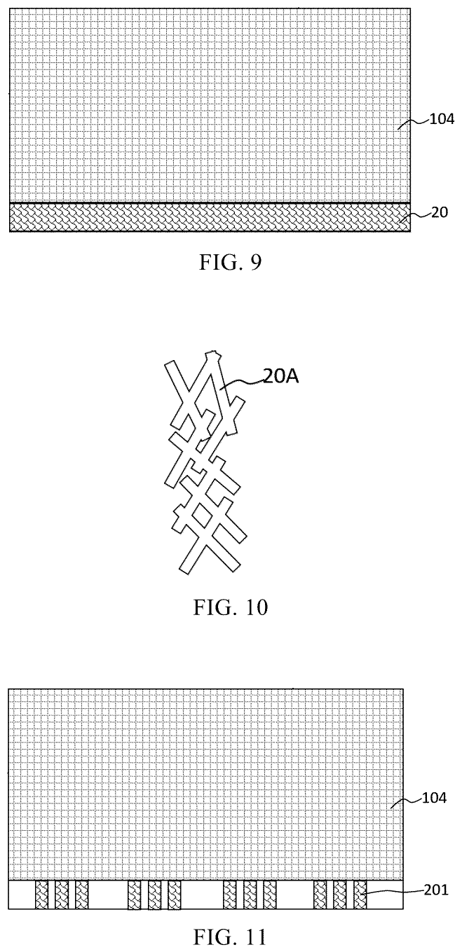

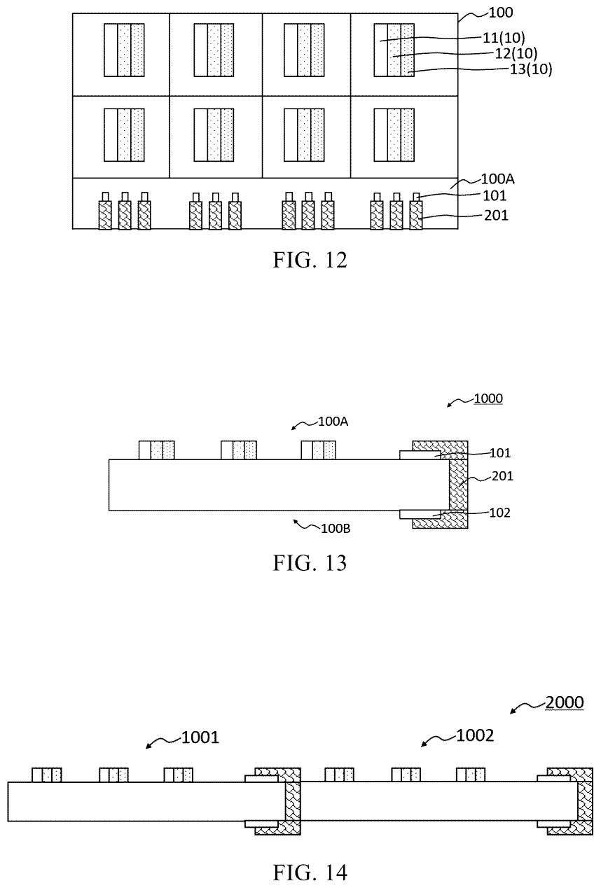

Please refer to FIGS. 1 to 13. FIG. 1 is a process flow diagram illustrating a manufacturing method of a display panel according to one embodiment of the present application. FIG. 2 is a schematic view of a first surface in a first intermediate step of the manufacturing method of the display panel according to one embodiment of the present application. FIG. 3 is a schematic view of a second surface in the first intermediate step of the manufacturing method of the display panel according to one embodiment of the present application. FIG. 4 is a first cross-sectional view along a dashed line C-D direction in FIG. 2. FIG. 5 is a second cross-section view along the dashed line C-D direction in FIG. 2, showing a situation where a first connection terminal and a corresponding second connection terminal are adjacent to or connected to a lateral end surface. FIG. 6 is a schematic view of the first surface in a second intermediate step of the manufacturing method of the display panel according to one embodiment of the present application. FIG. 7 is a schematic view of the first surface in a third intermediate step of the manufacturing method of the display panel according to one embodiment of the present application. FIG. 8 is a schematic view showing a state before sintering of a silver nanowire layer according to one embodiment of the present application. FIG. 9 is a schematic view of the first surface in a fourth intermediate step of the manufacturing method of the display panel according to one embodiment of the present application. FIG. 10 is a schematic view showing a state after sintering of the silver nanowire layer according to one embodiment of the present application. FIG. 11 is a schematic view of the first surface in a fifth intermediate step of the manufacturing method of the display panel according to one embodiment of the present application. FIG. 12 is a schematic view of the first surface in a sixth intermediate process of the manufacturing method of the display panel according to one embodiment of the present application. FIG. 13 is a schematic cross-sectional view of the display panel according to one embodiment of the present application. Understandably, when the first connecting terminal as shown in FIG. 2 and the corresponding second connecting terminal are adjacent to or connected with the lateral end surface, a sectional schematic view as shown in FIG. 5 can be obtained along the dashed line C-D direction.

The manufacturing method of the display panel provided by one embodiment of the present application includes the following steps: S100, S200. S300, S400, S500. The numbering of the steps in the embodiment is for the convenience of explaining the manufacturing process, rather than limiting the manufacturing sequence.

Step S100: providing a substrate to be processed, wherein the substrate to be processed includes a first surface, a second surface, and a lateral end surface disposed between the first surface and the second surface, the first surface is provided with a first connection terminal, and the second surface is provided with a second connection terminal corresponding to the first connection terminal.

Specifically, a substrate to be processed 100 is provided. The substrate to be processed 100 includes a first surface 100A, a second surface 100B, and a lateral end surface 103 disposed between the first surface 100A and the second surface 100B. The first surface 100A is provided with a first connection terminal 101, and the second surface 100B is provided with a second connection terminal 102 corresponding to the first connection terminal 101.

Specifically, as shown in FIG. 2, the substrate to be processed 100 includes the first surface 100A and the second surface 100B. The first surface 100A is a front side of the substrate to be processed 100, and the first surface 100A is a side or a surface where micro light-emitting diodes are arranged on the substrate to be processed 100. As shown in FIG. 3, the second surface 100B is a back side of the substrate to be processed 100, and the second surface 100B is a side or a surface where a driver chip is set or bonded on the substrate to be processed 100.

Specifically, it is easy to understand, as shown in FIG. 4 or FIG. 5, the first connection terminal 101 is arranged corresponding to the corresponding second connection terminal 102, and the first connection terminal 101 and the corresponding second connection terminal 102 are disposed close to the lateral end surface 103. FIG. 4. illustrates a state where the first connection terminal 101 and the corresponding second connection terminal 102 are not adjacent or connected to the lateral end surface 103. FIG. 5 illustrates a state where the first connection terminal 101 and the corresponding second connection terminal 102 are adjacent or connected to the lateral end surface 103.

Step S200: forming a first protective layer at least on the first surface, the first protective layer non-overlapping with the first connection terminal.

Specifically, as shown in FIG. 4 and FIG. 6, a first protective layer 104 is formed at least on the first surface 100A, and the first protective layer 104 non-overlaps with the first connection terminal 101.

Specifically, the first protective layer 104 covers the first surface 100A and exposes the first connection terminal 101. The first protective layer 104 covers the first surface 100A and exposes at least partial area where the first connection terminal 101 is located.

Step S300: forming a silver nanowire layer at least on the lateral end surface of the substrate to be processed, wherein the silver nanowire layer is connected to the first connection terminal and the second connection terminal.

Specifically, as shown in FIG. 7, a silver nanowire layer 20 is formed at least on the lateral end surface 103 of the substrate to be processed 100, and the silver nanowire layer 20 is connected to the first connection terminal 101 and the second connection terminal 102.

Step S400: sintering the silver nanowire layer with ultraviolet laser.

Specifically, as shown in FIGS. 7, 8, 9, and 10, the silver nanowire layer 20 is sintered by the ultraviolet laser.

Specifically, FIG. 7 is a top view showing a state before sintering of the silver nanowire layer. FIG. 8 illustrates a state before sintering of the silver nanowire layer. FIG. 9 illustrates a top view showing a state after sintering of the silver nanowire layer. FIG. 10 illustrates a sintered state of the silver nanowire layer.

In the present embodiment, as shown in FIGS. 7, 8, 9, and 10, the silver nanowire layer 20 is formed at least on the lateral end surface 103 of the substrate to be processed 100. By sintering the silver nanowire layer 20, the contact or adhesion performance between subsequently formed connection wires 201 and the substrate to be processed 100, thereby preventing detachment of the connection wires 201. At the same time, sintering the silver nanowire layer 20 causes mutually contacting silver nanowires 20A to be fused together, avoiding insufficiently tight or poor contact between the silver nanowires 20A and reducing the impedance of the connection wires 201.

Step S500: patterning the silver nanowire layer to form a plurality of connection wires, wherein the connection wires are connected between the first connection terminal and the second connection terminal corresponding to the first connection terminal.

Specifically, as shown in FIGS. 11, 12, and 13, the silver nanowire layer 20 is patterned to form the connection wires 201. The connection wires 201 are connected between the first connection terminal 101 and the corresponding second connection terminal 102.

Specifically, FIG. 11 illustrates patterning the silver nanowire layer 20 to form the connecting wires 201. FIG. 12 illustrates that the first protective layer 104 is removed. FIG. 13 is a cross-sectional view after removing the first protective layer 104, or FIG. 13 is a cross-sectional view of the display panel.

In some embodiments, as shown in FIGS. 7 and 8, before the step of sintering the silver nanowire layer with the laser, the silver nanowire layer 20 includes the silver nanowires 20A. As shown in FIGS. 9 and 10, after the step of sintering the silver nanowire layer with the laser, the silver nanowires 20A that are in contact with each other are fused together.

Specifically, the fusion of the mutually contacting silver nanowires 20A mean that the silver nanowires 20A that are in contact with each other are melted at points of contact and cooled to form a unified structure. By sintering the silver nanowire layer 20, the mutually contacting silver nanowires 20A fuse together, enhancing the contact or adhesion performance of the connection wires 201 with the substrate to be processed 100, and preventing detachment of the connection wires 201. At the same time, sintering the silver nanowire layer 20 causes the mutually contacting silver nanowires 20A to fuse, avoiding insufficiently tight or poor contact between the silver nanowires 20A, thereby reducing the impedance of the connection wires 201.

Further, by covering portions of the silver nanowire layer 20 over sections of the first connection terminal 101 and the second connection terminal 102, the sintering process enhances the connection strength of the silver nanowire layer 20 and the connection wires 201 with the first connection terminal 101 and the second connection terminal 102, thereby avoiding detachment and also reducing the contact impedance.

Further, in some embodiments, in the sintering process, the silver nanowire layer 20 or the silver nanowires 20A in some sections can melt and cool down to form a solid connection with corresponding portions of the first connection terminal 101 and the second connection terminal 102. This results in the silver nanowire layer 20 or the silver nanowires 20A being integrally formed with certain portions of the first connection terminal 101 and the second connection terminal 102, thereby eliminating contact resistance and further reducing the impedance.

In some embodiments, the sintering of the silver nanowire layer is performed by laser sintering.

Specifically, the laser sintering can sinter specific portions of the silver nanowire layer 20, without affecting other portions of the silver nanowire layer 20, thus avoiding damage to other portions of the silver nanowire layer 20.

Specifically, the laser sintering can be performed by using an ultraviolet laser.

In some embodiments, the step of patterning the silver nanowire layer to form the connection wires is performed by using laser irradiation.

Specifically, laser engraving can be used to pattern the silver nanowire layer 20 into multiple connection wires 201. During the laser engraving process, edges of the connection wires 201 undergo an additional sintering, resulting in smooth and neat edges of the connection wires 201, preventing crack formation, further reducing the risk of detachment of the connection wires 201, and lowering the impedance.

In some embodiments, the step of forming the first protective layer at least on the first surface further includes forming a second protective layer (not illustrated) on the second surface 100B. The second protective layer non-overlaps with the second connection terminal 102.

Specifically, the second protective layer can also be formed on the second surface 100B. Similar to the first protective layer 104, the second protective layer non-overlaps with the second connection terminal 102, in order to arrange the silver nanowire layer 20.

In some embodiments, the first protective layer 104 is produced by coating or attaching.

In some embodiments, a material of the first protective layer 104 includes a polyimide.

In some embodiments, the step of forming the silver nanowire layer at least on the lateral end surface of the substrate to be processed further includes forming the silver nanowire layer on the first connection terminal 101 of the first surface 100A and the second connection terminal 102 of the second surface 100B.

Specifically, in the situation depicted in FIG. 5, the silver nanowire layer 20 can be formed only on the lateral end surface 103. In this case, the silver nanowire layer 20 can connect between the first connection terminal 101 and the second connection terminal 102.

Specifically, in the situation depicted in FIG. 4, it is necessary to also have the silver nanowire layer 20 cover part of the first connection terminal 101 and part of the second connection terminal 102. As a result, the silver nanowire layer 20 is simultaneously formed on part of the first connection terminal 101 of the first surface 100A, the lateral end surface 103, and part of the second connection terminal 102 of the second surface 100B.

It should be noted that the present embodiment also provides a display panel 1000. The display panel 1000 includes a plurality of light-emitting diodes (LED) 10. The light-emitting diodes 10 can include red light-emitting diodes 11, green light-emitting diodes 12, and blue light-emitting diodes 13; the present application is not limited in this regard.

It should be noted that the manufacturing method of the display panel can further include removing the first protective layer 104 or removing the first protective layer 104 and the second protective layer.

It should be noted that in this embodiment, by using silver nanowires for side-line connections, the present solution overcomes issues present in conventional silver paste side-line schemes, such as significant resistance differences, short circuits, open circuits, and susceptibility to abrasion. After sintering, the silver nanowire fully fuse together, greatly reducing side-line resistance, enhancing resistance to wire breaks, and improving adhesion. At the same time, the silver nanowire coating process is simple and quick, which overcomes the short circuit problem caused by high-temperature, long-duration metal infiltration for film formation in a deposited side-line scheme. The method of this embodiment is characterized by its simplicity, high production efficiency, low side-line resistance, uniform resistance distribution, strong adhesion, and excellent resistance to wire breaks. This significantly enhances the yield of side-line connections and the reliability of micro-LED or mini-LED display panels.

### Second Embodiment

Please refer to FIG. 14. FIG. 14 is a schematic view of a spliced display panel according to one embodiment of the present application.

One embodiment of the present application also provides a spliced display panel 2000. The spliced display panel 2000 includes a first sub-display panel 1001 and a second sub-display panel 1002 that are spliced together. The first sub-display panel 1001 is manufactured using the manufacturing method of the display panel in any of the above-mentioned embodiment. The second connection terminal 102 of the first sub-display panel 1001 is electrically connected to a driver chip.

Specifically, the spliced display panel 2000 includes the first sub-display panel 1001 and the second sub-display panel 1002 that are spliced together. At least the first sub-display panel 1001 is manufactured using the manufacturing method of the display panel described in any of the above embodiments. The first sub-display panel 1001 includes the first connection terminal 101 and the second connection terminal 102. The connection wires 201 are electrically connected between the first connection terminal 101 and the second connection terminal 102. The first surface 100A is provided with thin-film transistors and wiring. The wiring can include a scan line and a data line. Through the first connection terminal 101, the connection wires 201, and the second connection terminal 102, the wiring on the first surface 100A (the front side) of the first sub-display panel 1001 is conducted to the second surface 100B (the back side). Subsequently, the second connection terminal 102 is used to electrically connect to the driver chip or other driving systems. This design minimizes a width of a non-display area at the junction of the first sub-display panel 1001, reducing the size of a splice gap and even achieving seamless splicing.

In some embodiments, the spliced display panel 2000 further includes multiple miniature light-emitting diodes (micro LEDs or mini LEDs) arranged in an array on the first sub-display panel 1001 and the second sub-display panel 1002.

In some embodiments, the miniature LEDs 10 are used as backlight sources for the spliced display panel 2000 or sub-pixels for displaying images.

Specifically, the spliced display panel 2000 can be used as backlight sources of a liquid crystal display (LCD) panel, and the spliced display panel 2000 can also use micro LEDs or mini LEDs as pixels to directly display images, which is not limited herein. A manufacturing method of a display panel and a spliced display panel provided by the

present application are described above in detail. In the present disclosure, specific examples are used to illustrate the working principles and embodiments of the present application. The descriptions of the above embodiments are only used for ease of understanding the method and main ideas of the present application. According to the ideas of the present application, those skilled in the art can modify or change the embodiments and the application range. In summary, the present application should not be limited by the content of this specification.

1. A manufacturing method of a display panel, comprising steps as follows:
providing a substrate to be processed, wherein the substrate to be processed comprises a first surface, a second surface, and a lateral end surface disposed between the first surface and the second surface, the first surface is provided with a first connection terminal, and the second surface is provided with a second connection terminal corresponding to the first connection terminal;
forming a first protective layer at least on the first surface, the first protective layer non-overlapping with the first connection terminal;
forming a silver nanowire layer at least on the lateral end surface of the substrate to be processed, wherein the silver nanowire layer is connected to the first connection terminal and the second connection terminal;
sintering the silver nanowire layer with an ultraviolet laser; and
patterning the silver nanowire layer to form a plurality of connection wires, wherein the connection wires are connected between the first connection terminal and the second connection terminal corresponding to the first connection terminal.

2. The manufacturing method of the display panel according to claim 1, wherein before the step of sintering the silver nanowire layer with the ultraviolet laser, the silver nanowire layer comprises a plurality of silver nanowires; and
after the step of sintering the silver nanowire layer with the ultraviolet laser, the silver nanowires that are in contact with each other are fused together.

3. The manufacturing method of the display panel according to claim 1, wherein the step of patterning the silver nanowire layer to form the plurality of connection wires is performed by using laser irradiation.

4. The manufacturing method of the display panel according to claim 1, wherein the step of forming the first protective layer at least on the first surface further comprises forming a second protective layer on the second surface, the second protective layer non-overlapping with the second connection terminal.

5. The manufacturing method of the display panel according to claim 1, wherein the first protective layer is produced by coating or attaching.

6. The manufacturing method of the display panel according to claim 5, wherein a material of the first protective layer comprises polyimide.

7. The manufacturing method of the display panel according to claim 1, wherein the step of forming the silver nanowire layer at least on the lateral end surface of the substrate to be processed further comprises forming the silver nanowire layer on the first connection terminal of the first surface and the second connection terminal of the second surface.

8. A spliced display panel, comprising a first sub-display panel and a second sub-display panel spliced with each other, the first sub-display panel comprising:
a substrate to be processed, wherein the substrate to be processed comprises a first surface, a second surface, and a lateral end surface disposed between the first surface and the second surface, the first surface is provided with a first connection terminal, and the second surface is provided with a second connection terminal corresponding to the first connection terminal;
a first protective layer at least disposed on the first surface, the first protective layer non-overlapping with the first connection terminal;
a silver nanowire layer at least disposed on the lateral end surface of the substrate to be processed, wherein the silver nanowire layer is connected to the first connection terminal and the second connection terminal;
the silver nanowire layer sintered by an ultraviolet laser; and
a plurality of connection wires patterned by the silver nanowire layer, wherein the connection wires are connected between the first connection terminal and the second connection terminal corresponding to the first connection terminal,
wherein the second connection terminal of the first sub-display panel is electrically connected to a driving chip.

9. The spliced display panel according to claim 8, further comprising a plurality of micro light-emitting diodes (LEDs) arranged in an array on the first sub-display panel and the second sub-display panel.

10. The spliced display panel according to claim 9, wherein the micro LEDs are used as a backlight source of the spliced display panel or as sub-pixels for displaying images.

11. The spliced display panel according to claim 8, wherein before the step of sintering the silver nanowire layer with the ultraviolet laser, the silver nanowire layer comprises a plurality of silver nanowires; and
after the step of sintering the silver nanowire layer with the ultraviolet laser, the silver nanowires that are in contact with each other are fused together.

12. The spliced display panel according to claim 8, wherein the step of patterning the silver nanowire layer to form the plurality of connection wires is performed by using laser irradiation.

13. The spliced display panel according to claim 8, wherein the step of forming the first protective layer at least on the first surface further comprises forming a second protective layer on the second surface, the second protective layer non-overlapping with the second connection terminal.

14. The spliced display panel according to claim 8, wherein the first protective layer is produced by coating or attaching.

15. The spliced display panel according to claim 14, wherein a material of the first protective layer comprises polyimide.

16. The spliced display panel according to claim 8, wherein the step of forming the silver nanowire layer at least on the lateral end surface of the substrate to be processed further comprises forming the silver nanowire layer on the first connection terminal of the first surface and the second connection terminal of the second surface.
